(19) United States
(12) Patent Application Publication
(10) Pub. No.: US 2007/0120240 A1
(43) Pub. Date: May 31, 2007

(54) Circuit substrate and method of manufacture

(75) Inventors: Siang Sin Foo, Singapore (SG); Wee Yong Tay, Singapore (SG); Wai Kiong Poon, Singapore (SG)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/288,691

(22) Filed: Nov. 29, 2005

(51) Int. Cl. H01L 23/02

(52) U.S. Cl. 257/685

(57) ABSTRACT

An aspect of the present invention comprises a method of producing a circuit substrate comprising providing a substrate, coating the substrate with a conductive layer, patterning the conductive layer to form at least two circuits joined by a buss-line and forming a slot in the substrate beneath the buss-line. Another aspect of the present invention comprises a circuit substrate with at least two circuits joined by a buss-line and a slot in the substrate beneath the buss-line. Another aspect of the present invention comprises an integrated circuit package with the described circuit substrate.

### FIELD

The invention relates to the manufacture of integrated circuits.

### BACKGROUND

An integrated circuit (IC) is a thin chip consisting of at least two interconnected semiconductor devices such as transistors and resistors. Among the most advanced ICs today are the microprocessors which can drive a large number of devices, such as computers and cellular phones. ICs are very delicate. A tiny speck of dust or a drop of water can hinder their function. Lighting, magnets, vibration and shock may also cause malfunctions. To combat these problems, the IC is packaged so as to shut out external influences thereby protecting the IC within.

To enable the packaged IC to exchange signals with the outside components, lead structures usually in the form of ‘legs’ in the case of leaded packages and soldered balls in the case of Ball Grid Array (BGA), are attached to the IC package to allow signals to be sent to the semiconductor devices from the outside and the results of processing accessed. FIG. 1 shows a leaded package comprising an IC package 10 and metal legs 13. FIGS. 2A, 2B and 2C show the top view, side view and bottom view respectively, of a BGA package comprising an IC package 10 and solder balls 20 arranged at a distance (pitch) 16 apart.

BGA is a type of surface-mount packaging used for ICs. In a BGA, balls of solder are attached to the bottom of the package to conduct electrical signals from the IC to the Printed Circuit Board (PCB) it is placed on. The package is placed on a PCB that carries copper pads in a pattern that matches the solder ball pattern. The assembly is then heated, either in a reflow oven or by an infrared heater, causing the solder balls to melt. Surface tension causes the molten solder to hold the package in alignment with the circuit board, at the correct separation distance, while the solder cools and solidifies. The solder does not completely melt, but stays semi-liquid, allowing each ball to stay separate from its neighbours. Using BGA, a miniature package for an IC with many hundreds of connections may be produced. A tape BGA (TBGA) is defined as any BGA package that uses flex circuitry as the substrate. With the superior wiring density of flex circuitry, a ball-array pattern that would normally require two or even four layers of circuit board to route, can now be accomplished on a single layer of flex circuitry.

Moisture is one of the major sources of corrosion for IC devices. Electro-oxidation and metal migration are associated with the presence of moisture. The extremely small geometries involved in ICs, different galvanic potentials between metal structures and the presence of high electric fields all make the device susceptible to interactions with moisture. To qualify an IC package for use, reliability testing is an integral part of the manufacturing process. Severe environmental tests including the Moisture Sensitivity Level (MSL) test, the biased Highly Accelerated Temperature and Humidity Stress Test (HAST), among others, have been devised to shorten testing and evaluation times.

The MSL test and biased HAST are carried out according to the IPC/JEDEC J-STD-020C and JEDEC JESD22-A110-B test method, respectively. The MSL test identifies the classification level of non-hermetic solid-state Surface Mount Devices (SMDs) that are sensitive to moisture-induced stress. The purpose of the biased HAST is to evaluate the reliability of non-hermetic packaged solid-state devices in humid environments. Two of the common failures observed in these tests are the delamination at the interface between the metallic traces and the flexible substrate during the MSL test and the electrical shortage of metallic traces due to dendritic growth during the biased HAST.

FIG. 3 shows the cross section of a TBGA. On the underside of the flexible substrate 30 are a series of solder balls 20 separated by pitch 16. On the opposite side of the flexible substrate 30 are metallic traces 32 of which some of the metallic traces 34 are embedded in a die attach paste 36. The die attach paste 36 bonds the die 39 to the embedded metallic traces 34 and the flexible substrate 30. A wire bond 42 connects the die 39 to the metallic traces 32 and all the elements on the side of the flexible substrate 30 opposite to the solder balls 20 are encapsulated by a mold compound 45. The metallic trace 32 and the flexible substrate 30 meet at interface 48.

IC packages subjected to thermal loads and/or moisture during processing and testing are vulnerable to delamination at all possible interfaces. Studies have found that differences in coefficients of thermal and moisture expansion are the driving factors for interface delamination in IC packages. There is evidence relating failure mechanisms such as passivation crack, wire shift and/or wire break, with the occurrence of delamination at the IC and the compound interface.

Delamination at the periphery of a TBGA has a detrimental effect on the IC package as it allows moisture and contaminants to easily diffuse into the package. Stored moisture can vaporise during rapid heating, which can lead to hydrostatic pressure during the reflow process. ‘Popcorn’ cracking caused by the expansion of trapped moisture in the package as the moisture changed from the liquid state to vapour state, aggravate the problem further causing more delamination and cracking.

FIGS. 4A to 4D shows digital images of flexible circuits in TBGA packages with solder ball locations 22 and dendrites 50 at the end of some metallic traces 32. Dendrites are metallic filaments which are created as a result of electrochemical migration between two points. Electrochemical migration refers to the transportation of ions between two metallization stripes under a biasing condition through an aqueous electrolyte. The consequence of this electrochemical migration is the creation of metallic dendrites which may result in a short circuit failure between two adjacent electrically biased conductors which may then lead to the failure or reliability problem in the microcircuits.

FIG. 5 shows a classical model for electrochemical migration. Anode 52 is anodically dissolved from its initial location and redeposited as metal at the cathodic site 56 forming dendrite 50 growing towards anode 52. The ions 54 are able to migrate from anode 52 to cathode 56 because of the presence of a polar transport medium 58 which may come in the form of water moisture at the interface and in the presence of an electric field between the anode and cathode. Finally, it is found that dendritic growth usually occurs at the periphery of a TBGA package.

### SUMMARY

In broad terms in one aspect the invention comprises a method of forming a circuit substrate comprising providing a substrate, coating the substrate with a conductive layer, patterning the conductive layer to form at least two circuits joined by a buss-line, and forming a slot in the substrate beneath the buss-line. The substrate is preferably flexible and may be a dielectric material, such as a polyimide. The patterning of the conductive layer may be done by photolithography. The slot may be formed by chemical etching or laser skiving.

In at least one embodiment the method of forming a circuit substrate further comprises attaching a carrier to the substrate. Preferably the carrier is rigid or is a removable adherent liner or is a removable stiffener tape.

In at least one embodiment the method of forming a circuit substrate further comprises applying a molding resin to the substrate and the circuit to form IC packages.

In at least one embodiment the method of forming a circuit substrate further comprises singulating the IC packages by dicing along the buss-lines.

In broad terms in another aspect the invention comprises a circuit substrate comprising a substrate with a layer of conductive material, the conductive layer patterned to form at least two circuits joined by a buss-line, and a slot in the substrate beneath the buss-line. The substrate is preferably flexible and may be a dielectric material, such as a polyimide. The patterning of the conductive layer may be done by photolithography. The slot may be formed by chemical etching or laser skiving.

In at least one embodiment the substrate is further attached to at least one carrier. Preferably the carrier is either rigid or is a removable adherent liner or is a removable stiffener tape.

In broad terms in another aspect the invention comprises an integrated circuit package comprising the substrate with a layer of conductive material, the conductive layer patterned to form at least two circuits joined by a buss-line, and a slot in the substrate beneath the buss-line.

In at least one embodiment the integrated circuit package may further be attached with at least one means of connection, connecting the circuitry inside the package to the circuitry outside the package.

In at least one embodiment the means of connection is by at least one pin or by at least one solder ball. In at least one embodiment the means of connection is using leaded material.

In at least one embodiment the circuitry outside the integrated circuit package is on a printed circuit board.

Unless indicated otherwise, the term ‘flexible substrate’ is intended to cover a substrate that is flexible and may or may not have circuitry fabricated on it.

Unless indicated otherwise, the term ‘circuit substrate’ is intended to cover a substrate that has one or more circuits on it and the substrate may or may not be flexible.

### BRIEF DESCRIPTION OF DRAWINGS

The invention will be further described by way of example only and without intending to be limiting with reference to the following drawings, wherein:

FIG. 1 shows an example of a leaded package;

FIG. 2A shows the top view of a BGA package;

FIG. 2B shows the side view of a BGA package;

FIG. 2C shows the bottom view of a BGA package;

FIG. 3 shows the cross section of a TBGA package;

FIG. 4A to 4D show digital images of test samples of flexible circuits with dendrite formation;

FIG. 5 diagrammatically illustrates how a dendrite is formed;

FIG. 6A shows a possible subtractive manufacturing process flow for making flexible circuits;

FIG. 6B shows a possible semi-additive manufacturing process flow for making flexible circuits;

FIG. 7A shows the schematics of an electrolytic cell for plating metal from a solution of the metal salt;

FIG. 7B illustrates the relevance of buss-lines in the electroplating process;

FIG. 8A is a perspective view of an exemplary embodiment of the invention after the substrate has been etched and before the tie layer has been etched;

FIG. 8B is a perspective view of an exemplary embodiment of the invention after the tie layer has been etched;

FIG. 9 shows the possible locations of the slots according to the invention in relation to the flexible circuit for each individual TBGA package;

FIG. 10A shows the cross section of a TBGA with additional slots incorporated according to the invention;

FIG. 10B shows a side view of a TBGA with mold compound between metallic traces according to the invention;

FIG. 11 shows the conventional process steps for the assembly and test of TBGA packages.

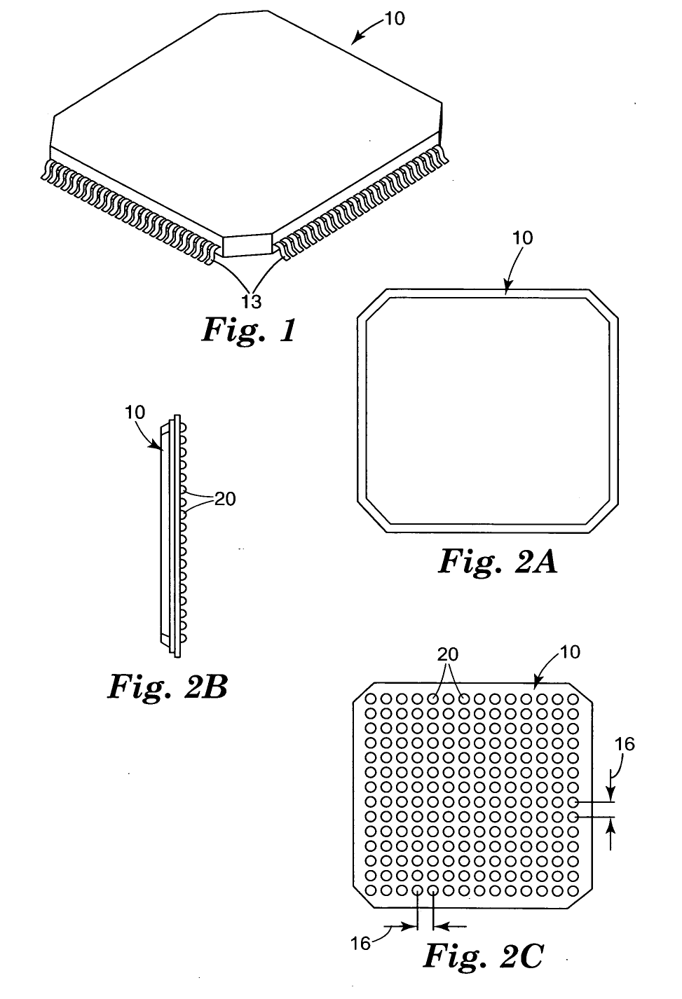

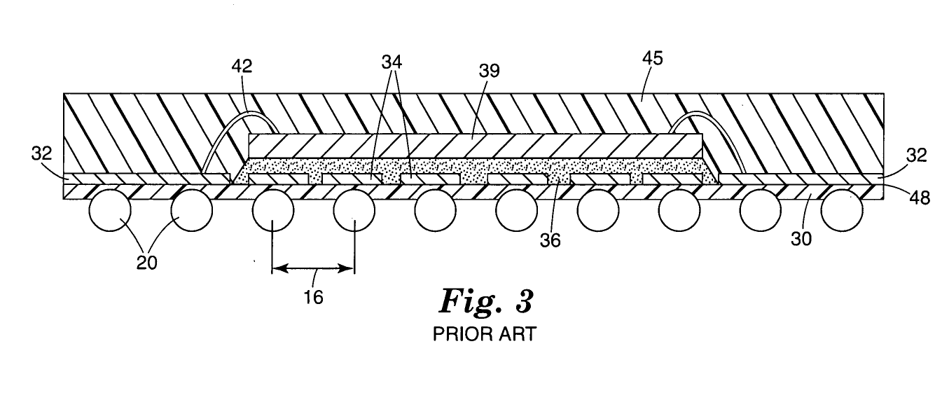

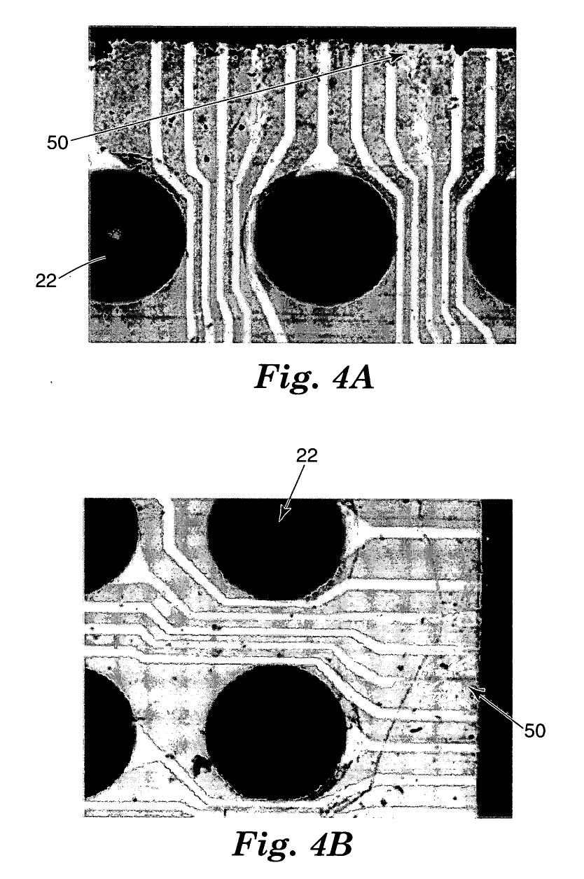

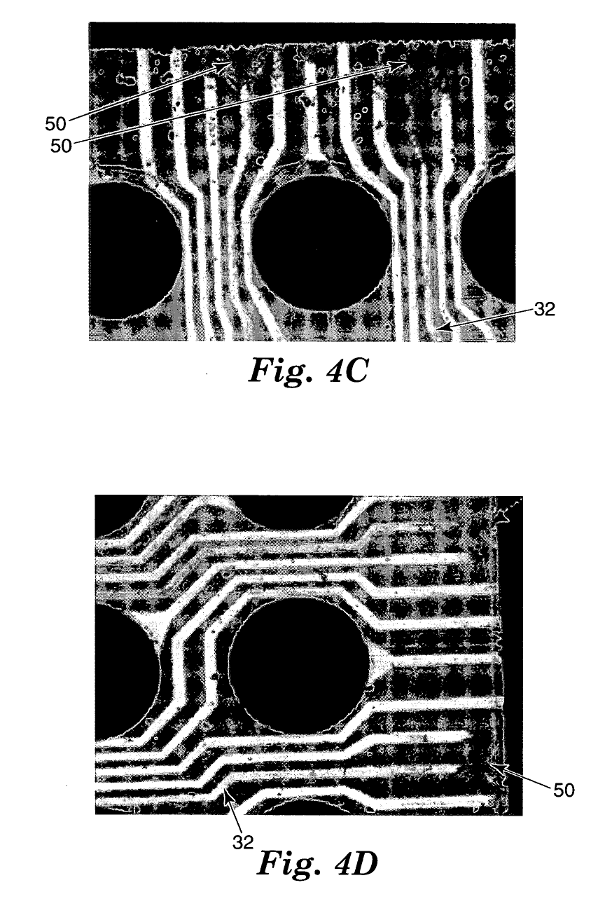

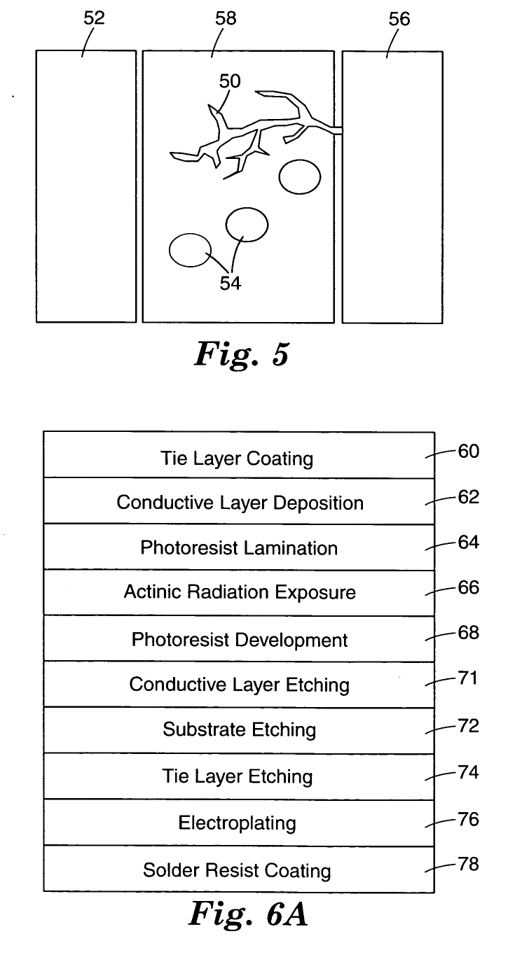

### DETAILED DESCRIPTION

The present invention relates to a circuit substrate with superior environmental performance.

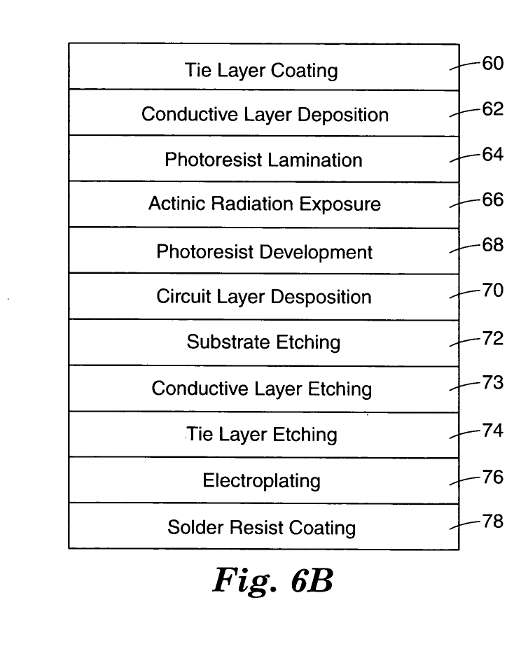

Circuits may be made by a number of suitable methods such as subtractive, additive-subtractive, and semi-additive. FIG. 6A shows a subtractive manufacturing process flow for flexible circuits using photolithography as the means of patterning the circuit. Other well-known methods may be used in place of photolithography for patterning the circuit.

In a typical subtractive circuit-making process, a substrate usually having a thickness of about 10 microns to about 150 microns is first provided.

The substrate serves to insulate the conductors from each other and provides much of the mechanical strength of the circuit. Other attributes of the substrate may include flexibility, thinness, high temperature performance, etchability, size reduction, and weight reduction, among others.

Many different materials may be used as substrates for flexible circuit manufacture. The substrate choice is dependent on a combination of factors including economics, end-product application and assembly technology to be used for components on the finished product.

A suitable substrate material is polyimide including, but not limited to, those available under the trade name APICAL, including APICAL NPI from Kaneka High-Tech Materials, Inc., Pasadena, Tex. (USA); and those available under the trade names KAPTON, including KAPTON E, KAPTON EN, KAPTON H, and KAPTON V from DuPont High Performance Materials, Circleville, Ohio (USA).

Other suitable substrate materials include polymers such as liquid crystal polymer (LCP), available from Kuraray High Performance Materials Division, Osaka (Japan); poly(ethylene terephthalate) (PET) and poly(ethylene naphthalate) (PEN), available under trade names of MYLAR and TEONEX respectively from DuPont Tiejin Films, Hopewell, Va. (USA); and polycarbonate available under trade name of LEXAN from General Electric Plastics, Pittsfield, Mass. (USA), among others.

Preferably the substrate is a polyimide. Desirably the substrate is flexible.

The substrate may first be coated with a tie layer as per step 60 in FIG. 6A. After a tie layer is deposited, a conductive layer may be deposited as per step 62 in FIG. 6A by known methods such as vapour deposition or sputtering. Optionally, the deposited conductive layer can be plated up further to a desired thickness by known electroplating or electroless plating processes. The desired thickness is typically the same as the desired thickness for the resulting circuit traces.

Electroplating, sometimes known as electrodeposition, is the process of producing a coating, usually metallic, on a surface by the action of an electric current. The deposition of a metallic coating onto an object is achieved by putting a negative charge on the object to be coated and immersing it into a solution, which contains a salt of the metal to be deposited. The metallic ions of the salt carry a positive charge and are thus attracted to the object. When they reach the negatively charged object that is to be electroplated, it provides electrons to reduce the positively charged ions to metallic form.

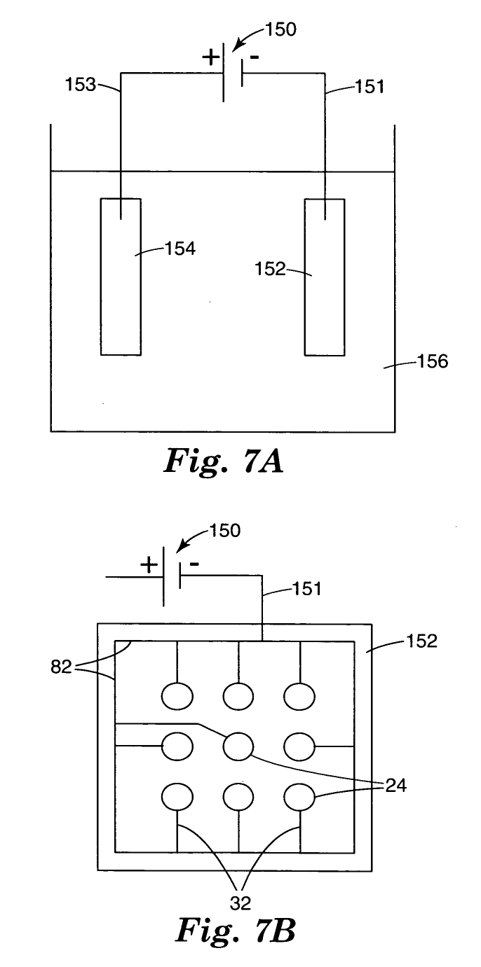

FIG. 7A gives a schematic presentation of an electrolytic cell for electroplating a metal from an aqueous solution of the metal salt. In the example illustrated by FIG. 7A, the object to be plated 152 is connected by a wire 151 to the negative pole of a power supply 150. The object to be plated may be any material on which the area to be plated is covered by a conductive material, typically a common metal such as copper. The positive pole of the power supply 150 is then connected via a wire 153 to a rod 154 which is made of the plating metal such as, but not limited to, nickel. The cell is then filled with a solution 156 of the metal salt to be plated. The metal salt, which may be, but is not limited to, nickel chloride, dissociates in water to positively charged nickel cations and negatively charged chloride anions. As the object to be plated 152 is negatively charged, it attracts the positively charged nickel cations and electrons flow from the object 152 to the cations to neutralise them to metallic form. Meanwhile the negatively charged chloride anions are attracted to the positively charged nickel rod 154 which is also known as the anode of the electrolytic cell. At the anode 154, electrons are removed from the nickel metal, oxidising it to the nickel cations. Thus, we see that the nickel dissolves as ions into the solution which is how replacement nickel is supplied to the solution for that which has been plated out and a solution of nickel chloride is maintained in the cell.

The conductive layer can be patterned using a number of well-known methods including photolithography. If photolithography is used, photoresists, which may be aqueous or solvent based, and may be negative or positive photoresists, are then laminated as per step 64 in FIG. 6A or coated on at least the metal-coated side of the substrate using standard laminating techniques with hot rollers or any number of coating techniques (e.g. knife coating, die coating, gravure roll coating, etc.).

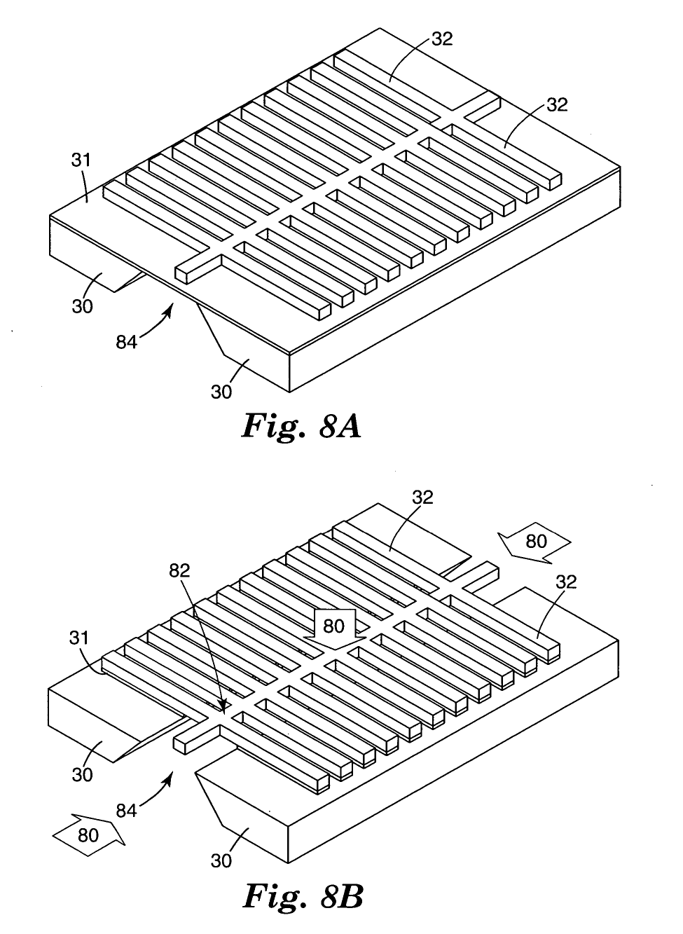

In an embodiment of the current invention, a separate layer of photoresist is laminated on the major side of the substrate opposite to the metal-coated side, during the same step 64 of FIG. 6A. This separate layer of photoresist is patterned to form a recess where the slot 84 in FIG. 8 is to be incorporated in the substrate after the etching step 72 in FIG. 6A.

The thickness of the photoresist typically ranges from about 1 micron to about 100 microns.

The photoresist is then exposed to actinic radiation, as per step 66 in FIG. 6A, for example ultraviolet light or the like, through a photomask or phototool. For a negative photoresist, the exposed portions are crosslinked and the unexposed portions of the photoresist are then developed with an appropriate solvent as per step 68 in FIG. 6A. For a subtractive process using negative photoresist, the remaining exposed photoresist pattern will be the same as the desired wiring pattern so that the conductive material between the desired wiring pattern can be removed.

The exposed portions of the conductive layer are then etched down to the tie layer using a suitable etchant as per step 71 of FIG. 6A. This is then followed by the etching of the exposed portions of the substrate on the major side opposite to the metal-coated side using an appropriate etchant as per step 72 of FIG. 6A. The slot 84 in the substrate 30 as shown in FIG. 8 is formed once step 72 of FIG. 6A is completed.

Then the exposed portions of the tie layer are etched away as per step 74 of FIG. 6A using a suitable etchant. The remaining (unexposed) conductive metal layer preferably has a final thickness ranging from about 5 microns to about 70 microns. The crosslinked photoresist is then stripped off the patterned circuit in a suitable solution. The circuit layer may form wiring on the substrate. The wiring may subsequently be plated with another metal, such as, but not limited to, gold, to protect the wiring as per step 76 of FIG. 6A.

FIG. 7B shows the front view of a section of the circuit substrate to be electroplated with a protective metal. The circular metallic traces 24 and the metallic traces 32 will be electroplated. For electroplating to take place, a negative charge must be placed on the features that are to be electroplated. In this case, a negative charge must be placed only on those metallic traces to be electroplated. This is made possible with the incorporation of buss-lines 82 which are then connected to the negative pole of the power supply 150 via a wire 151. The buss-lines provide the conductive connections to the metallic traces in each circuit substrate for electroplating.

Another possible method of forming the circuit portion would utilize semi-additive plating and the following typical step sequence as illustrated in FIG. 6B:

The conductive layer can be patterned in a manner similar to that described above in the subtractive circuit-making process. For a semi-additive process, a tie layer and a first conductive layer are deposited on a substrate, as per steps 60 and 62 of FIG. 6B. The materials and thicknesses of the substrate and conductive layer may be the same as those described in the previous paragraphs. Then a layer of photoresist is deposited on the first conductive layer as per step 64 of FIG. 6B. The photoresist is then patterned and developed such that the remaining photoresist forms a negative image of the desired circuit pattern as per steps 66 and 68 of FIG. 6B. The exposed portions of the first conductive layer are further plated using standard electroplating or electroless plating methods as per step 70 in FIG. 6B until the conductive material is thicker than the desired circuit thickness, which is in the range of about 5 microns to about 70 microns, by an amount about equal to the thickness of the first conductive layer.

The slot in the substrate on the major side opposite to the metal-coated side may be created in the same fashion as described in the subtractive process during step 72 of FIG. 6B.

The cross-linked exposed portions of the photoresist are then stripped off of the patterned circuit. Subsequently, the exposed portions of the thin first conductive layer are etched with an etchant that does not harm the substrate. The etchant will also remove material from the now-exposed circuit traces, bringing the thickness of the circuit traces to their desired thickness. The exposed portions of the tie layer are then removed with an appropriate etchant as per step 74 of FIG. 6B. The remaining conductive pattern will form wiring on the substrate.

The wiring may be plated with another metal to protect the wiring in the same fashion as that described in the previous paragraphs as per step 76 of FIG. 6B.

Another possible method of forming the circuit portion would utilize a combination of subtractive and additive plating, referred to as a subtractive-additive method, and the following typical step sequence:

A substrate may be coated with a tie layer. A thin first conductive layer may then be deposited using a vacuum sputtering or evaporation technique. The materials and thicknesses for the dielectric substrate and conductive layer may be as described in the subtractive process.

The conductive layer can be patterned by a number of well-known methods including photolithography, as described in the subtractive process. The photoresist forms a positive pattern of the desired pattern for the conductive layer, the exposed conductive material is etched away using a suitable etchant. The tie layer is then etched with a suitable etchant.

The patterned photoresist is then stripped. The desired metal trace thickness can then be achieved with additional plating to a final thickness of about 5 microns to 70 microns.

The slot in the substrate on the major side opposite to the metal-coated side may be created, and the wiring may be plated with another metal to protect the wiring, in the same fashion as that described in the subtractive process.

In each of the methods described above, subsequent processing steps, such as application of a covercoat or solder resist, as per step 78 of FIGS. 6A and 6B, and additional finish plating may then be carried out. The substrate may further be provided with one or more ICs.

It should be noted that the figures in this specification are not drawn to scale. The figures are drawn to explain the concept and/or illustrate the invention and should not be interpreted as scale drawings. It should also be noted that most of the figures represent cross sections of articles that are three-dimensional. The cross sections may sometimes be used to illustrate the different layers of a flexible circuit.

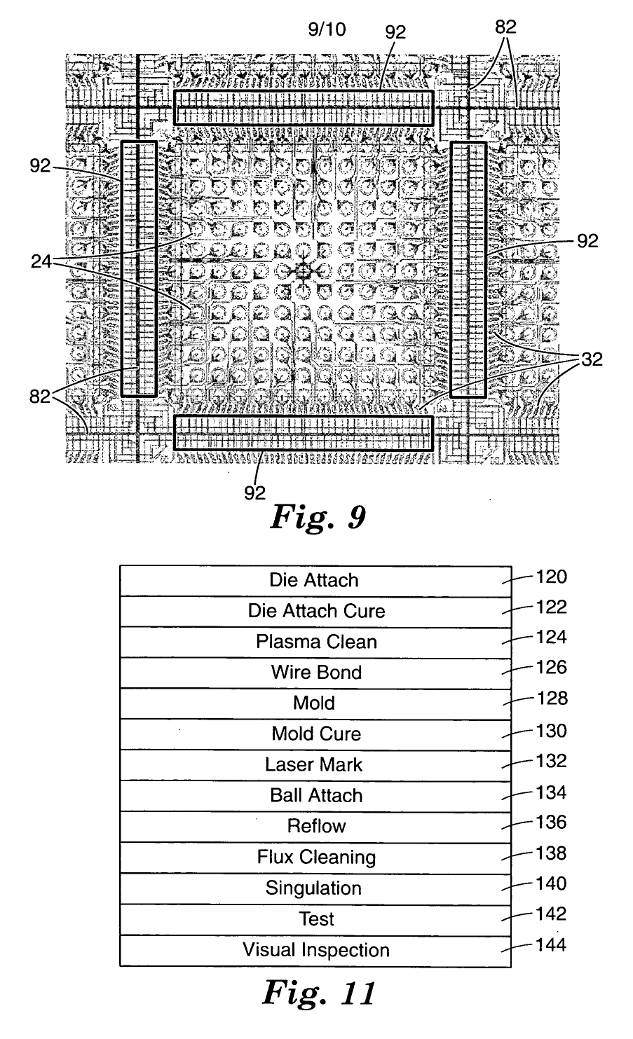

FIG. 8A and FIG. 8B depict different stages of a manufacturing process for an exemplary embodiment of the current invention incorporating slot 84 in the flexible substrate 30 between adjoining TBGA circuits such that the metallic traces 32 and buss-line 82 are suspended over the slot 84. In a conventional flexible circuit manufacturing process such as the subtractive and semi-additive process workflows shown in FIGS. 6A and 6B, the metallic traces are all connected to the buss-line for electroplating. The buss-line connecting the metallic traces has to be removed to isolate the metallic traces to prevent the metallic traces from being shorted during strip testing. Slot 84 may be created using various methods including chemical etching with an alkaline etchant such as potassium hydroxide during step 72 of FIGS. 6A and 6B or laser skiving using excimer laser, Neodymium laser, or Carbon Dioxide laser, among others. FIG. 8A is a perspective view of an exemplary embodiment of the invention after the substrate has been etched during the substrate etching step 72 of FIGS. 6A and 6B. The metallic traces 32 and buss-line 82 are positioned on the unetched tie layer 31. FIG. 8B is a perspective view of an exemplary embodiment of the invention after the tie layer 31 has been etched during the tie layer etching step 74 of FIGS. 6A and 6B. FIG. 9 is a top view of a section of a web with an array of flexible circuits for TBGA packages. Buss-lines 82 demarcate the perimeter of the flexible circuit for each individual TBGA package, circular metallic traces 24 identify the positions on which the solder balls will be placed on the opposite side of the flexible substrate and each circular metallic trace 24 ends with a corresponding metallic trace 32 which ends at a point on the buss-line 82. Short-circuiting of metallic traces 32 due to dendrite formation may occur if moisture is present to act as a polar transport medium. Outlines 92 mark the positions where the slots described in previous paragraphs may be created.

During the overmolding process as represented by steps 128 and 130 in FIG. 11, a mold compound is applied to encapsulate the metal traces and the buss-line. The mold compound will flow and fill the flexible substrate slot 84 from the directions as indicated by arrows 80 in FIG. 8B and encapsulate the suspended metallic traces 32 and buss-line 82. An example of such a mold compound may be, but is not limited to, an epoxy resin, such as that available under the trade designation EME-G770 from Sumitomo Bakelite Co., Ltd. After the overmolding process, the TBGA packages are singulated along the buss-lines 82 in FIG. 9 to form final individual TBGA packages.

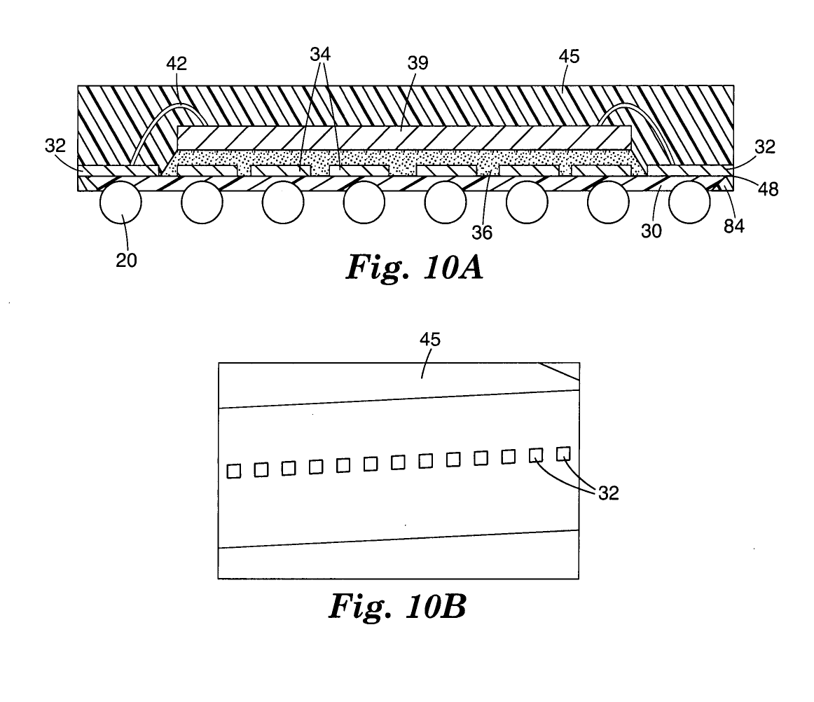

In accordance with an advantage of the present invention, the metallic traces 32 in FIG. 9 at the periphery of the TBGA package extend to the edge of the mold compound due to the incorporation of the slot 84 in FIG. 8 created at locations 92 in FIG. 9 in the flexible substrate. FIG. 10A gives an illustration of a possible end-result. FIG. 10B shows the side view of an TBGA package singulated at the location where the metallic traces 32 ends. As the space between each metallic trace 32 is now filled with the mold compound 45, it is not possible to have moisture between the metallic traces 32 and, therefore, there is no path for electrochemical migration to occur hence eliminating dendrite growth.

Another benefit of embedding the leads of the TBGA package in this way is the reduction in package failure due to delamination at interface 48 caused by environmental moisture absorption and seepage. As shown in FIG. 10A, the interface 48 is no longer in direct contact with the environment and so, the likelihood of moisture entering the TBGA package causing failure at the interface is drastically reduced.

FIG. 11 shows the conventional process steps for the assembly and test of TBGA packages which includes attaching the dies or chips to the flexible substrate using die attach paste (step 120), the die attach paste is then cured so that the dies or chips are fixed to the flexible substrate (step 122) and the end product at this stage is then cleaned (step 124) to be free from contaminants. The chips are wire bonded to the flexible substrate (step 126) and a mold compound is applied to encapsulate the chips to provide environmental protection (step 128). The mold compound is cured (step 130) and the mold is laser marked with chip identification information (step 132). The solder balls are aligned with the circular metallic traces on the chips (step 134) and permanently fixed to the chips after the reflow process (step 136). The chips with the solder balls are then cleaned (step 138) and singulated into individual IC packages (step 140). Each individual IC package undergoes different reliability tests (step 142) as well as visual test (step 144) before they are assembled.

In a typical flex-based IC assembly process, the flexible substrates may be handled with or without a carrier. In the carrier process, the flexible substrate is attached to a rigid piece of carrier before it can be used in the IC assembly process and this adds considerable cost to the manufacturing. In a carrierless process, the flexible substrate is used directly on the process line which not all IC packaging houses have the necessary capability to do.

It is desirable that the flexible substrate is flat and has a certain level of stiffness during the assembly process to prevent die cracking during the die attach process. If the flexible substrate is not flat when the die attach paste is dispensed and the die placed, then the die will not be uniformly supported during the overmold process which occurs under high pressure. This can result in bending and fracturing of the die.

Because it is very important that the flexible substrate be kept very flat during the assembly process, the strips of flexible substrate may be adhesively attached to rigid metal carriers. At some point in the process either after overmolding or after singulation the metal carrier is typically removed and is usually discarded, although it may be recycled.

In an embodiment of the current invention, a removable adherent liner or removable stiffener tape is added as a carrier to provide stiffness to the flexible substrate. The removable stiffener tape consists of an adhesive coated on a backing liner. The backing for the removable stiffener tape can be selected from a variety of films including polyimide and polyester films. Criteria for selecting an appropriate backing material include elastic modulus, thermal resistance, and thermal expansion coefficient. A thickness for the backing liner is chosen such that it will impart sufficient stiffness to enable handling in subsequent flexible substrate processing operations. The removable stiffener tape adhesive in this exemplary embodiment of the invention preferably provides uniquely balanced properties. Its bond strength to the flexible substrate should be sufficient to maintain adhesion through rigorous process steps yet the tape should be cleanly removable without damaging the delicate circuits. The adhesive is typically a highly crosslinked acrylic material that is formulated for use in semiconductor environments. Preferably, it contains no undesirable components, like silicone, and releases very cleanly from the flexible substrate. Preferably, no adhesive transfer to the flexible substrate is detected by ESCA methods. Additionally, the adhesive preferably has excellent thermal resistance (60 minutes at 150 degrees Celsius or 30 minutes at 175 degrees Celsius) and does not build adhesion during bake steps. An example of a stiffener tape with the earlier stated properties is available under the trade designation 7416P High Temperature Leadframe Tape from 3M Company, St. Paul, Minn.

Besides providing the flatness and stiffness level for the assembly of the IC packages, the removable stiffener tape also prevents the mold resin from leaking through slots 84 created in the flexible substrate during the overmolding process in steps 128 and 130 of FIG. 11. Leaking of the mold resin could contaminate the adjacent and supporting tooling thereby requiring the addition of an extra cleaning step in the assembly process. The removable stiffener tape may be attached to the flexible substrate before the die attach step in the assembly process with a simple nip roller type laminator. The removable stiffener tape may be peeled off from the flexible substrate after the overmold operation or prior to the final curing of the overmolding compound.

The foregoing describes the invention including preferred forms thereof. Alterations and modifications as will be obvious to those skilled in the art are intended to be incorporated in the scope hereof as defined by the accompanying claims.

1. A method of producing a circuit substrate comprising:
providing a substrate;
coating the substrate with a conductive layer,
patterning the conductive layer to form at least two circuits joined by a buss-line, and
forming a slot in the substrate beneath the buss-line.

2. A method of producing a circuit substrate as claimed in claim 1 wherein the substrate is flexible.

3. A method of producing a circuit substrate as claimed in claim 1 wherein the conductive layer is patterned using photolithography.

4. A method of producing a circuit substrate as claimed in claim 1 wherein the slot in the substrate beneath the buss-line is formed by chemical etching or laser skiving.

5. A method of producing a circuit substrate as claimed in claim 1 further comprising attaching a carrier to the substrate.

6. A method of producing a circuit substrate as claimed in claim 5 wherein the carrier is rigid.

7. A method of producing a circuit substrate as claimed in claim 5 wherein the carrier is one of a removable adherent liner and a removable stiffener tape.

8. A method of producing a circuit substrate as claimed in claim 1 further comprising applying a molding resin over the substrate and circuit to form IC packages.

9. A method of producing a circuit substrate as claimed in claim 8 further comprising singulating the IC packages by dicing along the buss-lines.

10. A circuit substrate comprising:
a substrate with a conductive layer,
the conductive layer patterned to form at least two circuits joined by a buss-line, and
a slot formed in the substrate beneath the buss-line.

11. A circuit substrate as claimed in claim 10 wherein the substrate is flexible.

12. A circuit substrate as claimed in claim 10 wherein the circuit substrate is attached to at least one carrier.

13. A circuit substrate as claimed in claim 12 wherein the carrier is rigid.

14. A circuit substrate as claimed in claim 12 wherein the carrier is one of a removable adherent liner and stiffener tape.

15. An integrated circuit package comprising the circuit substrate as claimed in claim 10.

16. An integrated circuit package as claimed in claim 15 wherein the package may is attached to at least one means of connection that connects circuitry inside the package to circuitry outside the package.

17. An integrated circuit package as claimed in claim 16 wherein the means of connection is by at least one pin.

18. An integrated circuit package as claimed in claim 16 wherein the means of connection is by at least one solder ball.

19. An integrated circuit package as claimed in claim 16 wherein the means of connection comprises using leaded material.

20. An integrated circuit package as claimed in claim 16 wherein the circuitry outside the package is on a printed circuit board.
